(19) United States
(12) Patent Application Publication
(10) Pub. No.: US 2003/0092249 A1
(43) Pub. Date: May 15, 2003

(54) Lightly-insitu-doped amorphous silicon applied in DRAM gates

(76) Inventors: Chia-Fu Hsu, Hsinchu (TW); Chin-Cheng Cheng, Hsainchu (TW)

Correspondence Address: NIXON PEABODY, LLP, 8180 GREENSBORO DRIVE, SUITE 800, MCLEAN, VA, 22102, US

(21) Appl. No.: 09/986,741

(22) Filed: Nov. 9, 2001

(51) Int. Cl. H01L 21/3205; H01L 21/4763

(52) U.S. Cl. 438/592

(57) ABSTRACT

The present invention forms a polysilicon by first forming then thermally processing a lightly in-situ doped amorphous silicon layer, thus suppressing boron penetration and lateral diffusion of N-type and P-type impurities.

### FIELD OF THE INVENTION

The present invention relates to lightly-insitu-doped amorphous silicon, and particularly to lightly-insitu-doped amorphous silicon applied in DRAM gates.

### BACKGROUND OF THE INVENTION

A Complementary Metal Oxide Semiconductor transistor (CMOS) includes an N-channel Metal Oxide Semiconductor Field Effect Transistor (NMOSFET) and a P-channel MOSFET (PMOSFET). If the CMOS is a twin wells construction, the twin wells are N-type and P-type well respectively. The CMOS, having advantages of low power assumption and high speed, is extensively used in many memory and logic circuits of semiconductor devices, such as a control transistor of a Dynamic Random Access Memory (DRAM).

Because there are electrodes for the NMOSFET and the PMOSFET of the CMOS, the CMOS includes P-type and N-type doped gates. Therefore, the N-type impurities, such as arsenic and phosphorus, and the P-type impurities, such as boron and boron difluoride, are respectively implanted into regions which NMOSFET and PMOSFET are to be formed.

Although many elements can be changed or modified, the CMOS still has a typical construction. Please refer to a prior art CMOS structure shown in FIG. 1, a region 101 which an NMOSFET is to be formed and a region 102 which a PMOSFET is to be formed are located on a substrate 100 and are separated from each other. The region 101 and region 102 can be separated by a shallow isolated trench 103, as shown in FIG. 1. Alternatively, a Local Oxidation of Semiconductor (LOCOS) process may be used. A gate oxide 104 is formed on the substrate 100, and on the gate oxide 104 is a polysilicon 105. The polysilicon 105 is usually formed by a chemical vapor deposition method.

The region 101 which an NMOSFET is to be formed is implanted by N-type ions, like phosphorous ions, to form an N-type well while the region 102 which a PMOSFET is to be formed is implanted by P-type ions, like boron ions, to form a P-type well. A conductive layer 110, like tungsten silicide, is formed over the polysilicon 105.

The formation of the typical CMOS construction includes steps as follows. First, as shown in FIG. 2a, a gate oxide 104 is deposited on the substrate 100, which includes a region 101 which an NMOSFET is to be formed, a region 102 which a PMOSFET is to be formed, and a device to separate the region 101 and region 102, such as a shallow trench isolation 103. Next, a polysilicon 105 is deposited on the gate oxide 104, as shown in FIG. 2b.

Then, as shown in FIG. 2c, the polysilicon 105 is covered and protected by a photoresist 106 except the region 101 which an NMOSFET is to be formed when the N-type ions 107 are implanted. Afterwards, as shown in FIG. 2d, the polysilicon 105 is covered and protected by a photoresist 108 expect the region 102 which a PMOSFET is to be formed when P-type ions 109 are implanted. After the N-type and P-type ions are implanted, typically the substrate 100 is thermally processed to activate the implanted ions. Finally, a conductive layer 110 is formed on the polysilicon 105 as shown in FIG. 2e. The steps of the ion implantation and the formation of conductive layer 110 can change their order as desired. Obviously, when conductive layer 110 is formed before ions are implanted, a driven-in step must be performed to force the ions to penetrate into the polysilicon 105.

As the integration density of semiconductors increases rapidly, the thickness of the gate oxide 104 becomes thinner and the boron penetration issue becomes a critical problem. The boron ions are easily penetrated through the gate oxide 104 and reach the polysilicon 105. The phenomenon of the boron penetration causes destruction of the gate oxide 104, the variation of threshold voltage and the gate depletion.

Additionally, it is found that speed of lateral diffusion of the N-type and P-type ions in the tungsten silicide of conductive layer 110 is faster than that in the polysilicon 105. After several succeeding necessary thermal processes, the Fermi energy of the polysilicon 105 varies and the gate is depleted.

As noted above, the typical CMOS construction faces two problems. One is boron penetration through the gate oxide and the other is lateral diffusion of the N-type and P-type ions.

In view of these problems, the present invention provide a method for suppressing boron penetration through the gate oxide and, at the same time, lateral diffusion of the N-type and P-type ions.

### SUMMERY OF THE INVENTION

An objective of the present invention is to provide a method for manufacturing a semiconductor device to suppressing the boron penetration and, at the same time, lateral diffusion of the N-type and P-type impurities.

The present invention provides a method for manufacturing a semiconductor device. The semiconductor device has a substrate, and the substrate includes the first conductive region of the first conductivity type and the second conductive region of the second conductivity type. The method includes steps stated as follows. First, a lightly-doped amorphous silicon layer is formed on the substrate and thermally processed to form a polysilicon layer. Next, a conductive layer is formed on the polysilicon layer. Finally, impurity ions of the first conductivity type are implanted into the polysilicon layer to form the first conductive region, and impurity ions of the second conductivity type are implanted into the polysilicon to form the second conductive region.

The step for forming the amorphous silicon layer is providing a compound gas and lightly in-situ doping the same during the deposition. In one preferred embodiment, when the lightly-doped dopant is arsenic or phosphorous ions, the compound gas contains arsenic or phosphorous ions, such as arsine or phosphine.

The silicon layer is lightly-doped amorphous silicon layer before thermally processing and is polysilicon layer after thermally processing. The lightly-doped amorphous silicon layer is formed by lightly-doping impurity ions of the first conductivity type in the first concentration, and the second conductive region of the second conductivity type in said polysilicon layer is doped by impurity ions of the second conductivity type in the second concentration. The second concentration is substantially larger than the first concentration.

### BRIEF DESCRIPTION OF THE DRAWINGS

FIG. 1 is schematic diagram showing a typical construction of a CMOS in accordance with the prior art.

FIG. 2a through FIG. 2e show detailed steps for forming the CMOS shown in FIG. 1.

FIG. 3a through FIG. 3f show detailed steps in accordance with the invention.

FIG. 4 is the flow diagram of the present invention.

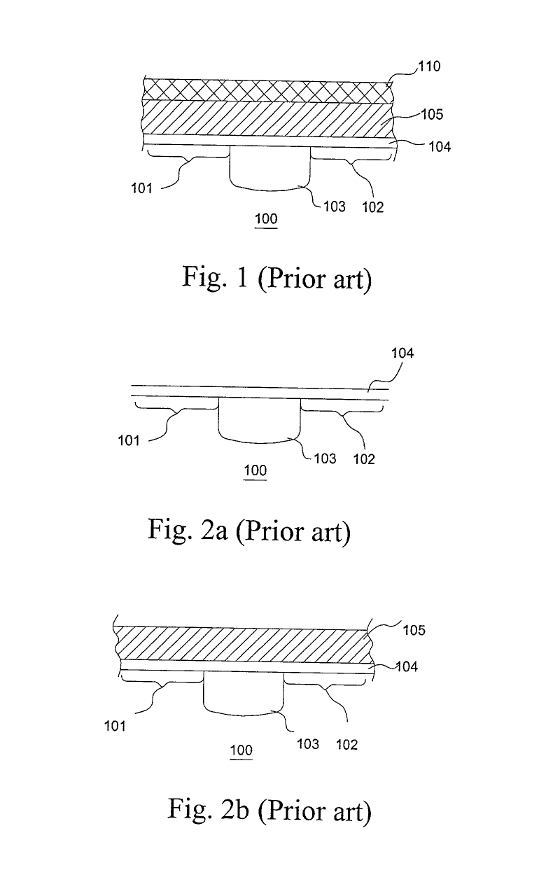

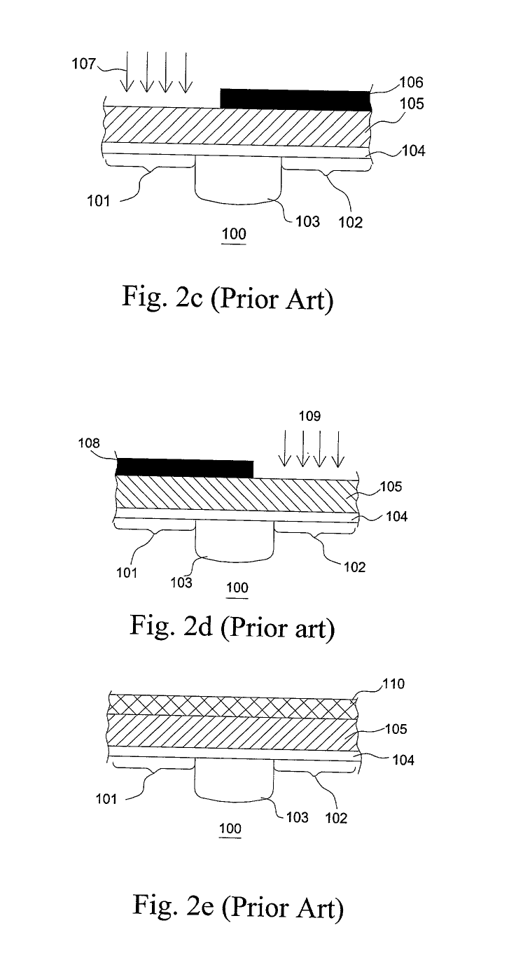

### DETAIL DESCRIPTION OF THE INVENTION

The present invention is to provide a method for manufacturing a semiconductor device, and the semiconductor device has a substrate. The substrate includes a first conductive region of a first conductivity type, a second conductive region of a second conductivity type, and an oxide is formed on the substrate.

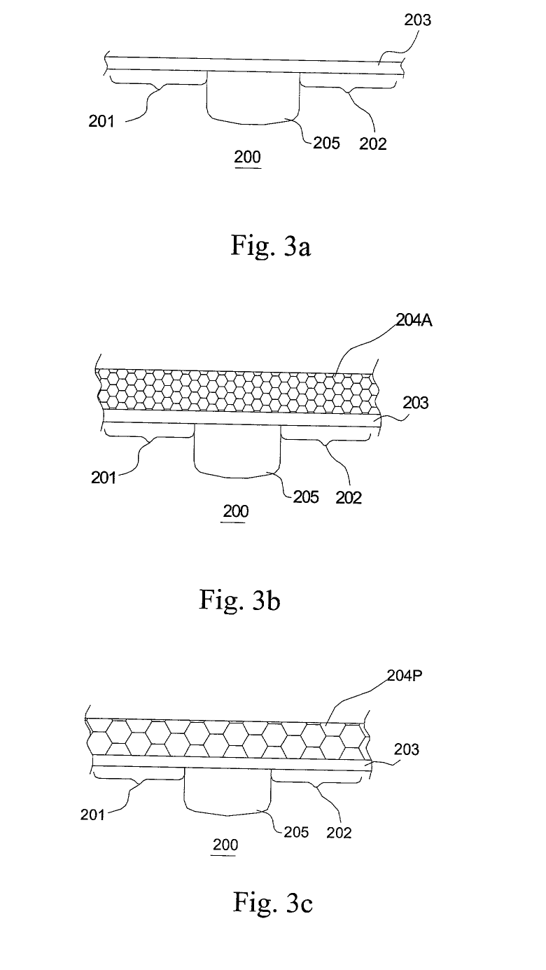

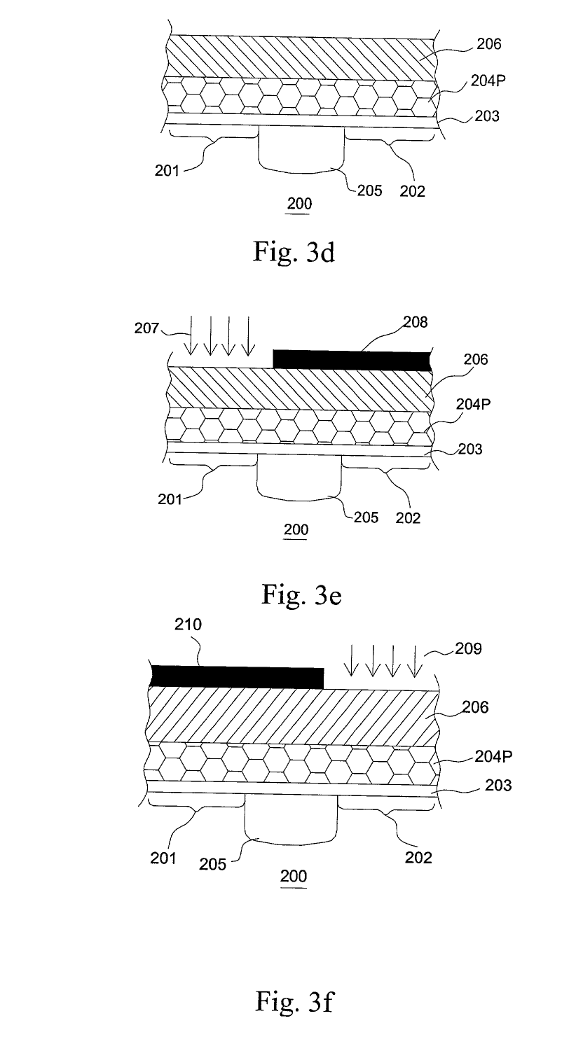

Please refer to FIG. 3a, a substrate 200 includes a region 201 which an NMOSFET is to be formed and a region 202 which a PMOSFET is to be formed. The regions 201 and 202 are separated by a shallow trench isolation 205, and a gate oxide 203 is on the substrate 200.

Afterwards, in a preferred embodiment, a lightly-doped amorphous silicon layer 204A is formed over the gate oxide 203, as shown in FIG. 3b. The “lightly-doped” indicates that the doped concentration in this stage is lighter than the finalized doped concentration of the region 201 and region 202.

The lightly-doped amorphous silicon layer 204A is usually formed by a chemical vapor deposition method, and the in-situ doped impurities is preferably N-type, such as phosphorous or arsenic ions. Afterwards, the lightly-doped amorphous silicon layer 204A is thermally processed and crystallized to form a polysilicon 204P, as shown in FIG. 3c. The silicon crystal, formed by first doping then thermally processing, has lager grains because doped impurities that provide nucleation sites enhance the formation of silicon grains. In this stage, the region 201 which an NMOSFET is to be formed and the region 202 which a PMOSFET is to be formed are both covered by the polysilicon 204P doped by N-type impurities.

Next, a conductive layer 206 is deposited on the polysilicon 204P, as shown in FIG. 3d. The preferable material of the conductive layer 206 are selected from a group consisting of tungsten silicide, titanium silicide, molybdenum silicide, tantalum silicide and cobalt silicide, and tungsten silicide is usually employed as the conductive layer 206. The conductive layer 206 improves the ohm contact between polysilicon 204P and Aluminum, which is not shown in the figure. The combination of the polysilicon 204P and the conductive layer 206 is also called polycide and is usually adopted as a gate contact.

Please refer to FIG. 3e, the conductive layer 206 is covered by the photoresist 208 expect the region 201, and the N-type ions 207 are implanted into the region 201 which an NMOSFET is to be formed. Subsequently, the conductive layer 206 is covered by photoresist 210 except the region 202, and the P-type ions 209 are implanted into the region 202 which a PMOSFET is to be formed, as shown in FIG. 3f. As described above, the polysilicon layer 204P already contains impurity ions and therefore the implanted concentration of impurity ions used in FIGS. 3e and FIG. 3f must be adjusted. For example, if the polysilicon 204P is previously doped by N-type impurities, the implanted concentration of N-type impurities has to be lower than the finalized doped concentration, while the concentration of the P-type impurities is substantially not affected by the N-type impurities previously lightly-doped. Therefore the doped concentration of P-type impurities in this stage is about the same as the final doped concentration. In a preferred embodiment, the preferable concentration is recited as follows. The lightly-doped concentration in the lightly-doped silicon 204A is about 1/10 to ½ of the final doped concentration, and the lightly-doped concentration of arsenic or phosphorous ions is about 1E14/cm² to 1E15/cm². The finalized concentration of arsenic or phosphorous ions in the region 201 which a NMOSFET is to be formed is about 6E15/cm², and the final concentration of boron in the region 202 which a PMOSFET is to be formed is about 1E15/cm² to 2E15/cm².

Due to the region 201 which an NMOSFET is to be formed and region 202 which a PMOSFET is to be formed both containing N-type impurities, lateral diffusion of ions is suppressed efficiently. Furthermore, the N-type and P-type impurities coexist in the region 202 which a PMOSFET is to be formed also suppresses the boron penetration.

The polysilicon 204P, which contains larger grains and fewer grain boundaries, relatively has fewer pathways for the boron penetrating into the gate oxide 203. Accordingly, the lateral diffusion of the N-type and P-type impurities and the vertical diffusion of boron penetration into gate oxide 203 are suppressed. In addition, because the diffusion pathways in the polysilicon 204P are reduced, the N-type and P-type impurities are hardly diffused to the conductive layer 206. It has been observed that most of lateral diffusion of N-type and P-type impurities is occurred in the conductive layer 206. Therefore, since the present invention suppresses the boron penetrated to the conductive layer 206, lateral diffusion of the N-type and P-type impurities is also minimized.

The present invention involves one lightly-doping during the lightly-doped amorphous silicon layer 204A formation and then another doping when ions 207 or 209 are implanted into the polysilicon layer 204P. With respect of doping process, the invention involves two-step doping. In a preferred embodiment, the lightly-doped amorphous silicon layer 204A is lightly-doped by arsenic or phosphorous ions while the deposition is performed. Afterwards, the lightly-doped amorphous silicon layer 204A is thermally processed. In order to allow grains growing sufficiently, the thermal process is usually an annealing process. Compared with boron ions, the diffusion rates of the phosphorous or arsenic ions are slower, and the phosphorous or arsenic ions do not vertically penetrate to the gate oxide 203 preventing the threshold voltage from varying. After the conductive layer 206 is formed, the second time of doping, which is an ion implanting, is performed.

In the shown preferred embodiment, conductive layer 206 is formed before implanting the ions. Because the shallower portion of the conductive layer 206 has some ions, the ions diffused from the polysilicon 204P in the upward direction are eased. If implanting the ions is performed first and then forming of conductive layer 206 is sequentially performed, the ions having the finalized doped concentration in the polysilicon 204P may diffuse to the conductive layer 206 and accelerate lateral diffusion of the N-type and P-type type ions. However, if these factors are considered and controlled in advance, in another embodiment, one may implant the ions and afterwards form conductive layer 206.

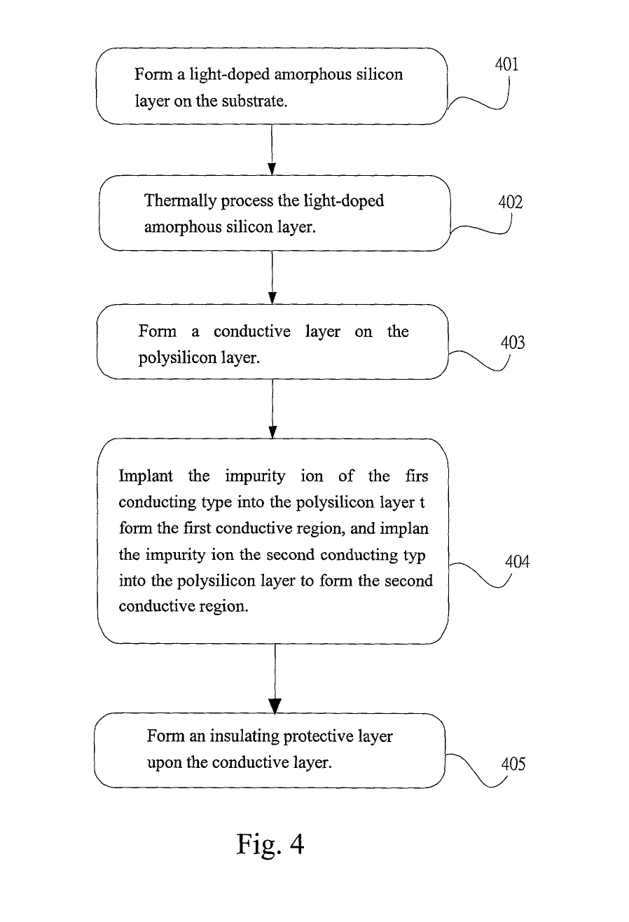

Please refer to FIG. 4 showing steps of the invention, the first step 401 is to form a lightly-doped amorphous silicon layer 204A on the gate oxide 203. Next, the step 402 is to thermally process the lightly-doped amorphous silicon layer 204A, such that the lightly-doped amorphous silicon 204A is crystallized to form polysilicon 204P, as shown in FIG. 3c. Then, a conductive layer 206 is formed on the polysilicon layer 204P in the step 403, as shown in FIG. 3d. Finally, in the step 404, the impurity ions of the first conducting type 207 are implanted into the polysilicon layer to form the first conductive region, and the impurity ions of the second conducting type 209 are implanted into the polysilicon layer to form the second conductive region. As shown is FIGS. 3e and 3f, the conductive layer 206 is partly covered by the photoresist 208 and 210 respectively, and N-type ions 207 and P-type ions 209 are implanted into the regions. Moreover, the method of the present invention may further include the step 405 for forming an insulating protective layer on the conductive layer 206.

It is to be understood that the steps 403 and 404 can change their order in the present invention.

It is appreciated by those skilled in the art that the present invention can be practiced in other specific ways without departing from the spirit and scope thereof, and therefore the provided embodiments here is illustrative but not restrictive. The scope of the invention should be determined not with reference to the above description but with reference with the appended claims with their full scope of equivalents.

What is claimed is:

1. A method for manufacturing a semiconductor device, said semiconductor device having a substrate, said substrate including a first conductive region of a first conductivity type and a second conductive region of a second conductivity type, comprising the steps of:
forming a lightly-doped amorphous silicon layer on said substrate;
thermally processing said lightly-doped amorphous silicon layer to form a polysilicon layer;
forming a conductive layer on said polysilicon layer; and
implanting impurity ions of a first conductivity type into said polysilicon layer to form said first conductive region, and implanting impurity ions of a second conductivity type into said polysilicon layer to form said second conductive region.

2. The method of claim 1, wherein said impurity ions of said first conductivity type is arsenic ion or phosphorus ion.

3. The method of claim 1, wherein:
said lightly-doped amorphous silicon layer is formed by lightly-doping said impurity ions of said first conductivity type in a first concentration;
said second conductive region of said second conductivity type in said polysilicon layer is doped by said impurity ions of said second conductivity type in a second concentration; and
said second concentration is substantially larger than said first concentration.

4. The method of claim 1, wherein a concentration corresponding to said lightly-doped step is about 1E14/cm² to 1E15/cm².

5. The method of claim 1, wherein a concentration corresponding to said implanting step of said impurity ions of said first conductivity type is about 6E15/cm².

6. The method of claim 1, wherein a concentration corresponding to said implanting step of said impurity ions of said second conductivity type is about 1E14/cm² to 1E15/cm².

7. The method of claim 1, further comprising a step of forming an insulating protective layer upon said conductive layer.

8. The method of claim 1, wherein material of said conductive layer is selected from a group of tungsten silicide, titanium silicide, molybdenum silicide, tantalum silicide and cobalt silicide.

9. A method for manufacturing a semiconductor device, said semiconductor device having a substrate, said substrate including a first conductive region of a first conductivity type and a second conductive region of a second conductivity type, comprising steps of:
forming a lightly-insitu-doped amorphous silicon on said substrate;
thermally processing said lightly-insitu-doped amorphous silicon layer to form a polysilicon layer;
forming a metal silicide layer on said polysilicon layer;
implanting an impurity ions of a first conductivity type into said polysilicon layer to form said first conductive region, and implanting an impurity ions of a second conductivity type into said polysilicon layer to form said second conductive region; and
forming a insulating protective layer on said metal silicide layer.

10. The method of claim 9, wherein said impurity ions of said first conductivity type is arsenic ion or phosphorous ion.

11. The method of claim 9, wherein:
said lightly-insitu-doped amorphous silicon layer is formed by lightly-insitu-doping said impurity ions of aid first conductivity type in a first concentration;
said second conductive region of said second conductivity type in said polysilicon layer is doped by said impurity ions of said second conductivity type in a second concentration; and
said second concentration is substantially larger than said first concentration.

12. The method of claim 9, wherein a concentration corresponding to lightly-insitu-doped step is about 1E14/cm² to 1E15/cm².

13. The method of claim 9, wherein a concentration corresponding to said implanting step of said impurity ions of said first conductivity type is about 6E15/cm².

14. The method of claim 9, wherein a concentration corresponding to said implanting step of said impurity ions of said second conductivity type is about 1E14/cm² to 1E15/cm².

15. A method for manufacturing a semiconductor device, said semiconductor device having a substrate, said substrate including a first conductive region of a first conductivity type and a second conductive region of a second conductivity type, comprising steps of:
forming a lightly-insitu-doped amorphous silicon layer on said substrate;
thermally processing said lightly-insitu-doped amorphous silicon layer to form a polysilicon layer;
implanting an impurity ions of a first conductivity type into said polysilicon layer to form said first conductive region, and implanting an impurity ions of a second conductivity type into said polysilicon layer to form said second conductive region;
forming a metal silicide layer on said lightly-insitu-doped amorphous silicon layer; and
forming a insulating protective layer on said metal silicide layer.

16. The method of claim 15, wherein said impurity ions of said first conductivity type is arsenic ion or phosphorous ion.

17. The method of claim 15, wherein:
said lightly-insitu-doped amorphous silicon layer is formed by lightly-insitu-doping said impurity ions of said first conductivity type in a first concentration;
said second conductive region of said second conductivity type in said polysilicon layer is doped by said impurity ions of said second conductivity type in a second concentration; and
said second concentration is substantially larger than said first concentration.

18. The method of claim 15, wherein a concentration corresponding to said lightly-insitu-doped step is about 1E14/cm² to 1E15/cm².

19. The method of claim 15, wherein a concentration corresponding to said implanting step of said impurity ions of said first conductivity type is about 6E15/cm².

20. The method of claim 15, wherein a concentration corresponding to said implanting step of said impurity ions of said second conductivity type is about 1E14/cm² to 1E15/cm².
